(19) United States
(12) Patent Application Publication
(10) Pub. No.: US 2014/0015108 A1
(43) Pub. Date: Jan. 16, 2014

(54) METHOD OF MANUFACTURING SINGLE CRYSTAL INGOT, AND SINGLE CRYSTAL INGOT AND WAFER MANUFACTURED THEREBY

(71) Applicants: Sang-Hee Kim, Seoul (KR); Jung-Ha Hwang, Gyeongbuk (KR); Young-Kyu Choi, Gyeongbuk (KR); Bok-Cheol Sim, Daegu (KR)

(72) Inventors: Sang-Hee Kim, Seoul (KR); Jung-Ha Hwang, Gyeongbuk (KR); Young-Kyu Choi, Gyeongbuk (KR); Bok-Cheol Sim, Daegu (KR)

(21) Appl. No.: 13/821,007

(22) PCT Filed: Mar. 20, 2012
(86) PCT No.: PCT/KR2012/001992

§ 371 Date: Mar. 5, 2013

(30) Foreign Application Priority Data
Mar. 28, 2011 (KR) 10-2011-0027632

(51) Int. Cl. H01L 29/36; H01L 21/02

(52) U.S. Cl. CPC H01L 29/36; H01L 21/02002
USPC 257/618; 117/13; 117/28; 117/21

(57) ABSTRACT

A method of manufacturing a single crystal ingot, and a single crystal ingot and a wafer manufactured thereby are provided. The method of manufacturing a single crystal ingot according to an embodiment includes forming a silicon melt in a crucible inside a chamber, preparing a seed crystal on the silicon melt, and growing a single crystal ingot from the silicon melt, and pressure of the chamber may be controlled in a range of 90 Torr to 500 Torr.

### CROSS-REFERENCE TO RELATED APPLICATIONS

The present application is a national phase application of P.C.T. application PCT/KR2012/001992 filed Mar. 20, 2012, which claims the priority benefit of Korean patent application 10-2011-0027632 filed Mar. 28, 2011, the disclosures of which are incorporated herein by reference.

### BACKGROUND OF THE INVENTION

1. Field of the Invention

The present disclosure relates to a method of manufacturing a single crystal ingot, and a single crystal ingot and a wafer manufactured thereby.

2. Description of the Related Art

A wafer must be manufactured in order to manufacture a semiconductor, and single crystal silicon must first be grown in a form of an ingot in order to manufacture the wafer. For this purpose, a Czochralski (CZ) method may be used.

According to the related art, in an N-type heavily doped single crystal ingot, crystal growth through heavy doping may be particularly difficult because a dopant introduced to adjust resistivity has volatile characteristics having a melting point lower than that of silicon (Si).

An in-plane radial resistivity gradient (RRG) may be high due to such characteristics and may be generated because volatilization of a dopant occurs higher at an edge in contact with an outer surface of an ingot than a center thereof. Accordingly, resistivity (RES) at the edge becomes higher than that at the center, and thus the N-type heavily doped single crystal ingot may have poor RRG characteristics in comparison to a P-type heavily doped single crystal ingot grown under the same conditions.

Therefore, according to the related art, manufacturing specifications may be satisfied, but uniformity may be poor because RRG may overall high and distribution thereof may not be uniform.

In particular, with respect to power devices having recently growing market demand, importance of RRG characteristics, i.e. in-plane RES characteristics, may be overlooked or uniformity of RRG may not be obtained even in the case that importance of the uniformity of RRG is recognized.

### SUMMARY OF THE CLAIMED INVENTION

### Technical Problem

Embodiments provide a method of manufacturing a single crystal ingot having uniform radial resistivity gradient (RRG) characteristics, i.e., in-plane resistance (RES) values of a wafer, and a single crystal ingot and a wafer manufactured thereby.

Embodiments also provide a method of manufacturing a high-quality N-type heavily doped single crystal ingot having yield improved by control of a RRG within 5%, and a single crystal ingot and a wafer manufactured thereby.

### Solution to Problem

In one embodiment, a method of manufacturing a single crystal ingot includes: forming a silicon melt in a crucible inside a chamber; preparing a seed crystal on the silicon melt; and growing a single crystal ingot from the silicon melt, wherein pressure of the chamber may be controlled in a range of 90 Torr to 500 Torr.

In another embodiment, a silicon wafer may have a RRG (radial resistivity gradient) controlled within 5%.

In further another embodiment, a single crystal ingot may have a RRG (radial resistivity gradient) controlled within 5%.

The details of one or more embodiments are set forth in the accompanying drawings and the description below. Other features will be apparent from the description and drawings, and from the claims.

### ADVANTAGEOUS EFFECTS OF INVENTION

Embodiments provide a method of manufacturing an N-type heavily doped single crystal ingot having an uniformity of the in-plane RES value of a wafer controlled within 3%, and a single crystal ingot and a wafer manufactured thereby.

Also, according to the embodiments, a high-quality N-type heavily doped single crystal ingot having yield improved by control of a RRG within 5% and a wafer may be grown.

For example, according to the embodiment, with respect to N-type crystal growth in which a dopant introduced to adjust resistivity has volatile characteristics having a melting point lower than that of silicon, N-type heavily doped single crystal ingot and wafer, in which RRG and uniformity of a product particularly heavily doped at a concentration of 5E17 atoms/cc or more are respectively controlled within 5% and 3%, and a manufacturing method thereof are provided. Therefore, high-quality N-type heavily doped crystal and wafer having improved yield may be provided.

### BRIEF DESCRIPTION OF THE DRAWINGS

FIG. 1 is an exemplary view illustrating a single crystal ingot grower used for a method of manufacturing a single crystal ingot according to an embodiment;

FIG. 2 is an exemplary view illustrating an in-plane resistivity (RES) distribution of a wafer according to the embodiment;

FIG. 3 is an exemplary view illustrating an in-plane RES distribution of a wafer of a comparative example;

FIG. 4 is an exemplary view illustrating a schematic of the in-plane RES distribution of the wafer according to the embodiment;

FIG. 5 is an exemplary view illustrating a schematic of the in-plane RES distribution of the wafer of the comparative example; and

FIG. 6 is an exemplary view illustrating a curved interface L between a silicon melt and an ingot according to the embodiment.

### DETAILED DESCRIPTION

### Mode for the Invention

In the description of embodiments, it will be understood that when a wafer, apparatus, chuck, member, part, region or plane is referred to as being “on” and “under” another wafer, apparatus, chuck, member, part, region or plane, the terminology of “on” and “under” includes both the meanings of “directly” and “indirectly”. Further, the reference about “on” and “under” each element will be made on the basis of drawings.

Since the thickness or size of each element in the drawings may be modified for convenience in description and clarity, the size of each element does not entirely reflect an actual size.

### Embodiment

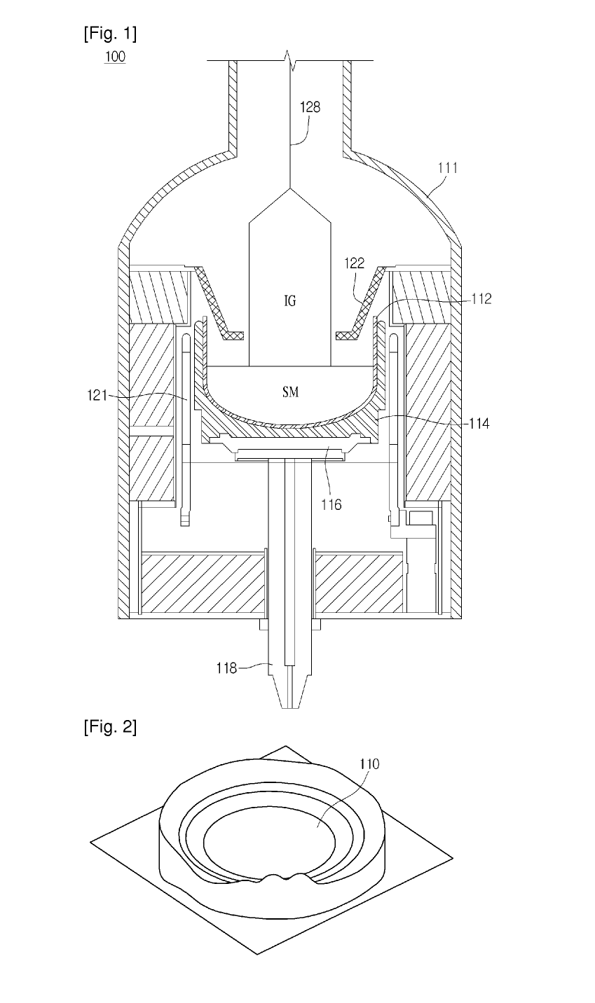

FIG. 1 is an exemplary view illustrating a single crystal ingot grower used for a method of manufacturing a single crystal ingot according to an embodiment.

A silicon single crystal ingot grower 100 according to the embodiment may include a chamber 111, a quartz crucible 112, a heater 121, and a pulling means 128.

For example, the silicon single crystal ingot grower 100 according to the embodiment may include the quartz crucible 112 containing a silicon melt SM and a graphite crucible 114 supporting the quartz crucible 112 by covering a part of an external lower portion thereof, as hot zone structures in the chamber 111, and a supporting structure 116 for supporting a load is disposed under the graphite crucible 114, in which the supporting structure 116 may be combined with a pedestal 118 connected to a rotary driving device (not shown) to be rotated and moved up and down.

The chamber 111 provides a space, in which predetermined processes for growing a single crystal ingot for a silicon wafer used as a material for an electronic component, such as a semiconductor, are performed.

The outside of the graphite crucible 114 is enclosed by a heater 121 which is a heat source supplying heat energy required for the growth of a single crystal ingot IG as radiation heat, and a side radiation shield (not shown) surrounds the outside of the heater 121 for shielding heat in order not to allow the heat of the heater 121 to be released to a side of the chamber 111.

A bottom radiation shield (not shown) may be installed in order not to allow the heat of the heater 121 to be released to a lower portion of the chamber 111 from a lower portion of the heater 121.

A top radiation shield (not shown) may be installed at an upper portion of the side radiation shield in order not to allow the heat of the heater 121 to be released to an upper portion of the chamber 111.

In the top radiation shield, a heat shield 122, which shields heat released from the silicon melt SM by being disposed between the single crystal ingot IG and the quartz crucible 112 to surround the single crystal ingot IG, and is configured to increase a driving force for cooling by shielding radiation heat leased from the silicon melt SM and transferred to the silicon ingot IG for cooling the grown silicon ingot, may be installed.

At the upper portion of the chamber 111, a driving device for pulling, dipping a seed crystal connected to the pulling means 128 in the silicon melt SM and growing an ingot by pulling while rotating at a predetermined speed, is installed, and a gas supply pipe (not shown) supplying inert gas such as argon (Ar) or neon (Ne) in the chamber 111 may be formed.

A vacuum exhaust pipe (not shown), which is connected to a vacuum exhaust pipe system (not shown) to exhaust the inert gas supplied from the gas supply pipe by pumping to vacuum, may be formed at the lower portion of the chamber 111.

Herein, the inert gas, which is supplied from the gas supply pipe to the inside of the chamber 111 by means of a vacuum pumping force of the vacuum exhaust pipe, may have a down flow.

The embodiment may use a Czochralski (CZ) method, in which a single crystal seed is dipped in the silicon melt SM and a crystal is then grown by being slowly pulled therefrom, as a manufacturing method of growing a silicon single crystal ingot.

According to the foregoing method, a necking process for growing a thin and long crystal from the seed crystal is first undertaken and then a shouldering process for growing the crystal in a radial direction to obtain a target diameter is undertaken. Thereafter, a body growing process for growing into a crystal having a predetermined diameter is undertaken and the diameter of the crystal is gradually decreased after the body growing up to a predetermined length is performed. Eventually, single crystal growth is completed through a tailing process for separating a single crystal ingot from the molten silicon.

The embodiment may provide a method of manufacturing a single crystal ingot having uniform radial resistivity gradient (RRG) characteristics, i.e., in-plane resistance (RES) values of a wafer, and a single crystal ingot and a wafer manufactured thereby.

The embodiment may also provide a method of manufacturing a high-quality N-type heavily doped single crystal ingot having yield improved by control of a RRG within 5%, and a single crystal ingot and a wafer manufactured thereby.

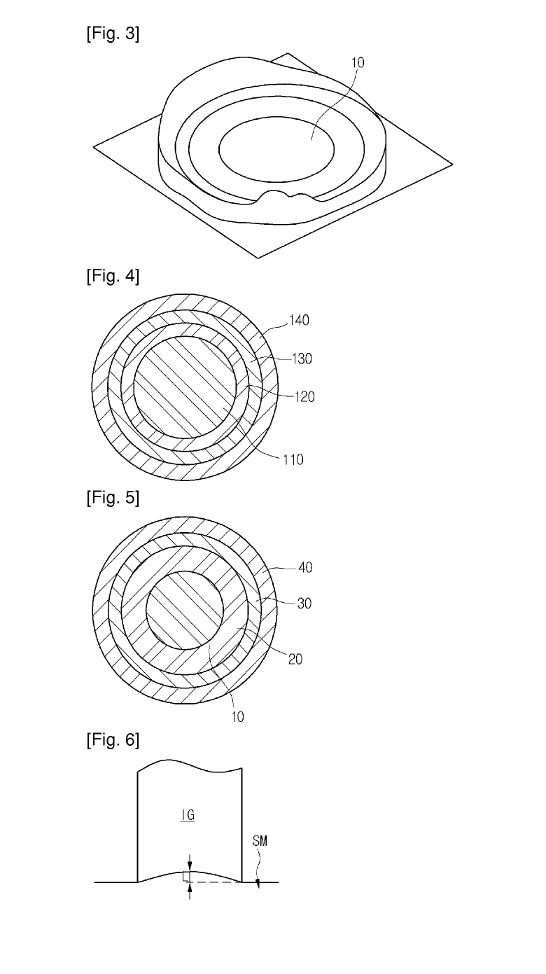

FIG. 2 is an exemplary view illustrating an in-plane RES distribution of a wafer according to the embodiment and FIG. 3 is an exemplary view illustrating an in-plane RES distribution of a wafer of a comparative example.

For example, FIGS. 2 and 3 are examples, in which in-plane RES values were measured by a 4-point probe, but the embodiment is not limited thereto.

As shown in FIG. 2, when the distribution of in-plane RES of a single crystal ingot and a wafer according to the embodiment are examined, it may be confirmed that a size of a circle 110 is greater than that of a circle 10 in FIG. 3.

This means that the wafer according to the embodiment has a wider uniform area of the RES value at the center. Also, it may be confirmed that a gap of the same region (the same RES) is uniform at an edge portion. This means that the distribution of in-plane RES is also uniform.

The embodiment may provide a method of manufacturing an N-type heavily doped single crystal ingot having an uniformity of the in-plane RES value of a wafer controlled within 3%, and a single crystal ingot and a wafer manufactured thereby.

Also, according to the embodiment, a high-quality N-type heavily doped single crystal ingot having yield improved by control of a RRG within 5% and a wafer may be grown.

For example, according to the embodiment, with respect to N-type crystal growth in which a dopant introduced to adjust resistivity has volatile characteristics having a melting point lower than that of silicon (Si), N-type heavily doped single crystal ingot and wafer, in which RRG and uniformity of a product heavily doped at a concentration of 5E17 atoms/cc are respectively controlled within 5% and 3%, and a manufacturing method thereof may be provided. Therefore, high-quality N-type heavily doped crystal and wafer having improved yield may be provided.

FIG. 4 is an exemplary view illustrating a schematic of the in-plane RES distribution of the wafer according to the embodiment and FIG. 5 is an exemplary view illustrating a schematic of the in-plane RES distribution of the wafer of the comparative example.

A cross section in a direction perpendicular to a growth axis direction of the single crystal ingot and wafer according to the embodiment may include a first region 110 having a center and a RES value within 0.0001 Ω-cm, a second region 120 having a RES value of 0.0001 Ω-cm higher than that of the first region 110, and a third region 130 having a RES value of 0.0001 Ω-cm higher than that of the second region 120. Also, in the embodiment, a fourth region 140 having a RES value higher than that of the third region 130 may be included.

A wafer surface area of the first region 110 in the embodiment was about 31% of a total area of the cross section, but a wafer surface area of a first region 10 in the comparative example was only about 22%. The comparative example may include a second region 20 having a RES value higher than that of the first region 10, a third region 30 having a RES value higher than that of the second region 20, and a fourth region 40 having a RES value higher than that of the third region 30.

Also, an area sum of the first region 110, the second region 120, and the third region 130 in the embodiment was about 76% or more of the total area of the cross section, but an area sum of the first region 10, the second region 20, and the third region 30 in the comparative example was only about 71%.

Samples of the embodiment and the comparative example were used for a power supply device (PSD) to measure yields. Both samples satisfied manufacturing specifications, but a yield of the sample of the embodiment was about 99.4% while a yield of the sample of the comparative example was about 98.9%, and thus a yield difference of about 0.5% was generated. In particular, a large yield difference was generated in the fourth region 140.

The embodiment may provide a method of manufacturing an N-type heavily doped single crystal ingot having an uniformity of the in-plane RES value of a wafer controlled within 3%, and a single crystal ingot and a wafer manufactured thereby.

Also, according to the embodiment, a high-quality N-type heavily doped single crystal ingot having yield improved by control of a RRG within 5% and a wafer may be grown.

For example, according to the embodiment, with respect to N-type crystal growth in which a dopant introduced to adjust resistivity has volatile characteristics having a melting point lower than that of silicon, N-type heavily doped single crystal ingot and wafer, in which RRG and uniformity of a product particularly heavily doped at a concentration of 5E17 atoms/cc or more are respectively controlled within 5% and 3%, and a manufacturing method thereof may be provided. Therefore, high-quality N-type heavily doped crystal and wafer having improved yield may be provided.

According to the embodiment, since an area for each region was difficult to be obtained all the time, the area was represented by typical RRG and uniformity values, and all samples satisfied manufacturing specifications of client companies. However, respective control of RRG and uniformity within 5% and 3% for obtaining higher yield may greatly affect the yield of a powder device.

TABLE 1

| | | | Yield | | |
|---|---|---|---|---|---|
| | Resistivity | RRG | (average) | Uniformity | Area for each region |
| Embodiment | 0.00286 Ωcm | 5% | 99.4% | 2.8% | First region: 31-33% First |
| | | | | | to third regions: 76-78% |
| Comparative | 0.00279 Ωcm | 9% | 98.9% | 4.1% | First region: 22-25% First |
| example | | | | | to third regions: 71-73% |

where uniformity = ((Max. value − Min. Value)/Max. value) × 100%, RRG = ((Avg. 4 points − Center 1 point)/Center 1 point) × 100%, Edge: 10 mm

According to the embodiment, pressure inside the chamber may be controlled in a range of 90 Torr to 500 Torr in order to prevent volatilization of a dopant at an outer surface (the third region 130 and the fourth region 140, particularly the fourth region 140) of the edge during single crystal growth.

When the pressure of the chamber is less than 90 Torr, resistivity may increase due to the volatilization of the dopant at an outer portion of the ingot, and discharge of oxide may be facilitated during ingot growth according to the CZ method when the pressure of the chamber is controlled to 500 Torr or less.

Also, according to the embodiment, as shown in FIG. 6, a curved interface L between the silicon melt SM and the ingot IG may be controlled in a range of 3 mm to 10 mm in order to secure the area of the first region 110, a center portion, as large as possible.

A height of the curved interface L may be controlled by adjusting seed rotation velocity or crucible rotation velocity.

FIG. 6 illustrates the curved interface L having a convex shape, but the embodiment is not limited thereto.

Therefore, the curved interface L may have a concave shape. At this time, a depth of the curved interface L may be within a range of 3 mm to 10 mm.

According to the embodiment, the silicon melt may be heavily doped with an N-type dopant, for example, at a concentration of 5E17 atoms/cc or more. As a result, according to the embodiment, RES of the single crystal ingot or wafer may be controlled to 0.001 Ω-cm or less.

As described above, embodiments provide a method of manufacturing an N-type heavily doped single crystal ingot having an uniformity of the in-plane RES value of a wafer controlled within 3%, and a single crystal ingot and a wafer manufactured thereby.

Also, according to the embodiments, a high-quality N-type heavily doped single crystal ingot having yield improved by control of a RRG within 5% and a wafer may be grown.

For example, according to the embodiments, with respect to N-type crystal growth in which a dopant introduced to adjust resistivity has volatile characteristics having a melting point lower than that of silicon, N-type heavily doped single crystal ingot and wafer, in which RRG and uniformity of a product particularly heavily doped at a concentration of 5E17 atoms/cc or more are respectively controlled within 5% and 3%, and a manufacturing method thereof are provided. Therefore, high-quality N-type heavily doped crystal and wafer having improved yield may be provided.

Features, structures, or effects described in the foregoing embodiment are included in at least one embodiment of the present invention, and are not necessarily limited to only one embodiment thereof. Further, the features, structures, or effects exemplified in each embodiment may be combined or modified by those skilled in the art and implemented to other embodiments thereof. Therefore, descriptions related to such combinations and modifications will be construed as being included in the scope of the present invention.

Also, while this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A method of manufacturing a single crystal ingot, the method comprising:
forming a silicon melt in a crucible inside a chamber;
preparing a seed crystal on the silicon melt; and
growing a single crystal ingot from the silicon melt, wherein pressure of the chamber is controlled in a range of about 90 Torr to about 500 Torr.

2. The method according to claim 1, wherein the growing of the ingot comprises controlling an interface between the silicon melt and the single crystal ingot.

3. The method according to claim 2, wherein rotation velocity of the seed crystal or rotation velocity of the crucible is controlled in the controlling of the interface.

4. The method according to claim 2, wherein the interface is controlled in a range of about 3 mm to about 10 mm in the controlling of the interface.

5. The method according to claim 1, wherein the silicon melt is doped with an N-type dopant at a concentration of 5×1017 atoms/cc or more.

6. The method according to claim 1, wherein RES (resistivity) of the single crystal ingot is controlled to about 0.001 Ω-cm or less.

7. A silicon wafer having a RRG (radial resistivity gradient) controlled within about 5%.

8. The silicon wafer according to claim 7, wherein uniformity of the wafer is controlled within about 3%.

9. The silicon wafer according to claim 7, wherein the wafer comprises:
a first region having a center and a RES value within about 0.0001 Ω-cm;
a second region having a RES value of about 0.0001 Ω-cm higher than that of the first region; and
a third region having a RES value of 0.0001 Ω-cm higher than that of the second region.

10. The silicon wafer according to claim 9, wherein an area of the first region is about 31% or more of a total area of the wafer.

11. The silicon wafer according to claim 9, wherein an area sum of the first region, the second region, and the third region is about 76% or more of the total area of the wafer.

12. A single crystal ingot having a RRG (radial resistivity gradient) controlled within about 5%.

13. The single crystal ingot according to claim 12, wherein a cross section in a direction perpendicular to a growth axis direction of the single crystal ingot comprises:
a first region having a center and a RES value within about 0.0001 Ω-cm;
a second region having a RES value of about 0.0001 Ω-cm higher than that of the first region; and
a third region having a RES value of 0.0001 Ω-cm higher than that of the second region.

14. The single crystal ingot according to claim 13, wherein an area of the first region is about 31% or more of a total area of the cross section.

15. The single crystal ingot according to claim 13, wherein an area sum of the first region, the second region, and the third region is about 76% or more of the total area of the cross section.

16. The single crystal ingot according to claim 12, wherein uniformity in the cross section of the single crystal ingot is controlled within about 3%.
